(19) United States
(12) Patent Application Publication
(10) Pub. No.: US 2007/0111894 A1
(43) Pub. Date: May 17, 2007

(54) Target for sputtering

(75) Inventor: Ryo Suzuki, Ibaraki (JP)

Correspondence Address: HOWSON AND HOWSON, SUITE 210, 501 OFFICE CENTER DRIVE, FT WASHINGTON, PA, 19034, US

(73) Assignee: Nikki Materials Co., Ltd., Toyko (JP)

(21) Appl. No.: 10/566,300

(22) PCT Filed: Jul. 7, 2004
(86) PCT No.: PCT/JP04/09981

§ 371 Date: Jan. 25, 2006

(30) Foreign Application Priority Data
Sep. 3, 2003 (JP) 2003-310930

(51) Int. Cl. H01L 39/24

(52) U.S. Cl. 505/475

(57) ABSTRACT

A sputtering target that is a perovskite oxide represented by the chemical formula of Ra₁₋ₓAₓBO_{3-α} (wherein Ra represents a rare earth element consisting of Y, Sc and lanthanoid; A represents Ca, Mg, Ba or Sr; B represents a transition metal element such as Mn, Fe, Ni, Co or Cr; and 0<x≦0.5) and having a relative density of 95% or more and a purity of 3N or more. The above target comprising a perovskite oxide ceramic material is improved in density and exhibits enhanced strength, and thus can prevent the occurrence of fractures or cracks during the manufacture process, transfer process or sputtering operation of the target, which results in the improvement in yield. This target can further inhibit the generation of particles during deposition, which results in the improvement of the quality of the film and in the reduction of the generation of defective products.

### TECHNICAL FIELD

The present invention pertains to an oxide sputtering target that is of high density and capable of inhibiting the generation of fractures or cracks in the target.

### BACKGROUND ART

A perovskite oxide ceramic material represented by the chemical formula of Ra₁₋ₓAₓBO_{3-α} (wherein Ra represents a rare earth element consisting of Y, Sc and lanthanoid; A represents Ca, Mg, Ba or Sr; and B represents a transition metal element such as Mn, Fe, Ni, Co or Cr) is known as an oxide material having low electrical resistance, and is attracting attention as an oxygen electrode of a solid-oxide fuel cell or an electrode material of a semiconductor memory (e.g., refer to Japanese Patent Laid-Open Publication No. H1-200560).

Further, this system is traditionally known to show colossal magneto-resistance effect (CMR) at low temperatures, and applications to magnetic sensors utilizing this feature or to a recently published RRAM recently are anticipated (e.g., refer to “Emergence of Spin Injection and RRAM—Change of Principle Aiming for Reduction in Costs” NIKKEI ELECTRONICS 2003.1.20, pages 98 to 105).

Nevertheless, a high density material as a sputtering target for depositing a thin film of this system with the sputtering method did not exist heretofore.

When this kind of perovskite oxide ceramic material is used as a target, in the event the density is low and sufficient strength cannot be obtained, there are problems in that fractures or cracks would occur during the manufacturing process, transfer process or sputtering operation of the target, and the yield would deteriorate.

Further, there is another problem in that the generation of particles would increase during the deposition process, quality would deteriorate and defective products would increase. Therefore, the improvement of density in this kind of ceramic material target existed as an extremely formidable challenge.

### DISCLOSURE OF THE INVENTION

In order to overcome this problem, the present inventors discovered that a sputtering target having a relative density of 95% or more, average grain size of 100 μm or less and resistivity of 10 Ωcm or less could be manufactured by prescribing the substitution amount of the Ra site, subjecting this to hot pressing and sintering under an inert gas atmosphere, and thereafter performing heat treatment thereto in atmospheric air or oxidized atmosphere.

More specifically, the present invention provides: (1) a sputtering target that is a perovskite oxide represented by the chemical formula of Ra₁₋ₓAₓBO_{3-α} (wherein Ra represents a rare earth element consisting of Y, Sc and lanthanoid; A represents Ca, Mg, Ba or Sr; B represents a transition metal element such as Mn, Fe, Ni, Co or Cr; and 0<x≦0.5) and having a relative density of 95% or more and a purity of 3N or more (α represents an arbitrary number within the scope of <3); (2) the sputtering target according to (1) above, wherein the average crystal grain size is 100 μm or less; and (3) the sputtering target according to (1) or (2) above, wherein the resistivity is 10 Ωcm or less.

### EFFECT OF THE INVENTION

According to the above, it has become evident that this target is capable of making a significant contribution in inhibiting the occurrence of fractures or cracks during the manufacture process, transfer process or sputtering operation of the target, which results in the improvement in yield, and further inhibiting the generation of particles during sputtering, which results in the improvement of the quality of the film and in the reduction of the generation of defective products.

### BEST MODE FOR CARRYING OUT THE INVENTION

In the perovskite oxide represented by the chemical formula of Ra₁₋ₓAₓBO_{3-α} (wherein Ra represents a rare earth element consisting of Y, Sc and lanthanoid; A represents Ca, Mg, Ba or Sr; and B represents a transition metal element such as Mn, Fe, Ni, Co or Cr), as shown in the following Examples, the amount of x is adjusted to be within the range of 0<x≦0.5 by using high purity oxide raw materials that are respectively 3N or more for configuring the intended target.

After weighing and mixing the respective high purity oxide raw materials, calcination was performed thereto in atmospheric air within the temperature range of 600 to 1300° C., and crystal phase powder primarily having a perovskite structure was obtained. This powder was pulverized with a wet ball mill, dried in atmospheric air, and then hot pressed and sintered under an inert gas atmosphere such as Ar gas at 800 to 1500° C. and 100 kg/cm² or more for 0.5 hours or more.

Further, this hot pressed sintered body was subject to heat treatment at 800 to 1500° C. for roughly 1 hour in order to obtain a sintered body target.

The Ra₁₋ₓAₓBO_{3-α} perovskite oxide obtained as described above will become a high density target having a purity of 3N (99.9%) or more and a relative density of 95% or more. Further, the texture of the target obtained as described above was able to achieve an average crystal grain size of 100 μm or less and resistivity of 10 Ωcm or less.

The Examples are now explained. Incidentally, these Examples are merely illustrative, and the present invention shall in no way be limited thereby. In other words, the present invention shall only be limited by the scope of claim for a patent, and shall include the various modifications other than the Examples of this invention.

### EXAMPLE 1

Y₂O₃ as Ra having a purity of 4N, SrCO₃ and CaCO₃ as A, and MnO₂ powder were used. After weighing and mixing these to become a composition of Y₁₋ₓCaₓMnO_{3-α}, Y₁₋ₓSrₓMnO_{3-α} (x=0.1, 0.3, 0.5), this was subject to calcination in atmospheric air at 1000° C. in order to obtain crystal phase powder primarily having a perovskite structure.

This powder was pulverized With a wet ball mill, dried in atmospheric air, and then hot pressed and sintered under an inert gas atmosphere such as Ar gas at 1200° C. and 300 kg/cm² for 2 hours. Further, this hot pressed sintered body was subject to heat treatment at 1000° C. for 2 hours in order to obtain a sintered body. The density and crystal grain size of the obtained sintered body to become the target material were measured. The results are shown in Table 1.

TABLE 1
(Y₁₋ₓAₓMnO₃)

| Substitution | | Relative Density | Average Grain Size | Resistivity |
|---|---|---|---|---|
| Amount X | | (%) | (μm) | (Ω cm) |
| Ca | 0.1 | 99.8 | 34 | 2 |
| | 0.3 | 99 | 41 | 3 × 10⁻¹ |
| | 0.5 | 98.6 | 48 | 8 × 10⁻⁴ |
| Sr | 0.1 | 99.6 | 38 | 9 × 10⁻¹ |
| | 0.3 | 98.9 | 44 | 9 × 10⁻² |
| | 0.5 | 98.4 | 50 | 6 × 10⁻⁴ |

As shown in Table 1, the relative density in each of the foregoing cases was 98.4% or more, the average grain size was 50 μm or less, and the resistivity was 2 Ωcm or less, and it is evident that superior characteristics of low resistance and high density are obtained. As described later, when performing sputtering with this kind of target, the obtained results indicated that there were no generation of fractures or cracks, and the generation of particles also decreased.

### COMPARATIVE EXAMPLE 1

A sintered body having a composition of Y₁₋ₓCaₓMnO_{3-α}, Y₁₋ₓSrₓMnO_{3-α} was prepared under the same conditions as Example 1 other than that Ca and Sr Substitution x were made to be 0 and 0.7. Where x=0, although it was possible to obtain a sintered body having a relative density of 95% or more and an average grain size of 100 μm or less for both Ca and Sr, the resistivity of the sintered body was 100 Ωcm or more, and numerous cracks were formed in the target after sputtering. Further, the amount of particles generated on the film was also significantly high.

Meanwhile, with a composition where x=0.7, numerous cracks were formed on the surface of the sintered body due to the heat treatment performed in atmospheric air after the hot pressing and sintering, and fractures were formed during the machining process.

### EXAMPLE 2

A sintered body was prepared under the same conditions as Example 1 other than that Ra was made to be La₂(CO₃)₃ with a purity of 4N, and evaluated in the same manner. The relative density of the obtained sintered body was 95% or more, and the average grain size was 100 μm or less. The results are shown in Table 2.

Further, as a result of evaluating the deposition, the amount of particles on the 8-inch wafer was 100 or less, and the generation of fractures or cracks after the sputtering evaluation could not be acknowledged.

TABLE 2
(La₁₋ₓAₓMnO₃)

| Substitution | | Relative Density | Average Grain Size | Resistivity |
|---|---|---|---|---|
| Amount X | | (%) | (μm) | (Ω cm) |
| Ca | 0.1 | 99.3 | 45 | 5 × 10⁻¹ |
| | 0.3 | 98.5 | 50 | 4 × 10⁻² |
| | 0.5 | 97.7 | 59 | 6 × 10⁻⁴ |
| Sr | 0.1 | 99.5 | 39 | 3 × 10⁻¹ |
| | 0.3 | 98.9 | 44 | 2 × 10⁻² |
| | 0.5 | 98.2 | 47 | 2 × 10⁻⁴ |

### EXAMPLE 3

A sintered body was prepared under the same conditions as Example 1 other than that Ra was made to be CeO₂ with a purity of 4N, and evaluated in the same manner. The relative density of the obtained sintered body was 95% or more, and the average grain size was 100 μm or less.

Further, as a result of evaluating the deposition, the amount of particles on the 8-inch wafer was 100 or less, and the generation of fractures or cracks after the sputtering evaluation could not be acknowledged. The results are shown in Table 3.

TABLE 3
(Ce₁₋ₓAₓMnO₃)

| Substitution | | Relative Density | Average Grain Size | Resistivity |
|---|---|---|---|---|
| Amount X | | (%) | (μm) | (Ω cm) |
| Ca | 0.1 | 98.8 | 30 | 5 |
| | 0.3 | 97.4 | 34 | 8 × 10⁻¹ |
| | 0.5 | 96.8 | 35 | 8 × 10⁻³ |
| Sr | 0.1 | 98.9 | 28 | 4 |
| | 0.3 | 98 | 32 | 9 × 10⁻² |
| | 0.5 | 97.4 | 36 | 1 × 10⁻³ |

### EXAMPLE 4

A sintered body was prepared under the same conditions as Example 1 other than that Ra was made to be Pr₆O₁₁ with a purity of 4N, and evaluated in the same manner. The relative density of the obtained sintered body was 95% or more, and the average grain size was 100 μm or less.

Further, as a result of evaluating the deposition, the amount of particles on the 8-inch wafer was 100 or less, and the generation of fractures or cracks after the sputtering evaluation could not be acknowledged. The results are shown in Table 4.

TABLE 4
(Pr₁₋ₓAₓMnₒ₃)

| Substitution | | Relative Density | Average Grain Size | Resistivity |
|---|---|---|---|---|
| Amount X | | (%) | (μm) | (Ω cm) |
| Ca | 0.1 | 99.9 | 23 | 8 |
| | 0.3 | 99.8 | 28 | 9 × 10⁻² |
| | 0.5 | 99.5 | 30 | 5 × 10⁻³ |
| Sr | 0.1 | 99.9 | 20 | 5 |
| | 0.3 | 99.9 | 22 | 5 × 10⁻² |
| | 0.5 | 99.8 | 27 | 2 × 10⁻³ |

### EXAMPLE 5

A sintered body was prepared under the same conditions as Example 1 other than that Ra was made to be Nd₂O₃ with a purity of 4N, and evaluated in the same manner. The relative density of the obtained sintered body was 95% or more, and the average grain size was 100 μm or less.

Further, as a result of evaluating the deposition, the amount of particles on the 8-inch wafer was 100 or less, and the generation of fractures or cracks after the sputtering evaluation could not be acknowledged. The results are shown in Table 5.

TABLE 5
(Nd₁₋ₓAₓMnO₃)

| Substitution | | Relative Density | Average Grain Size | Resistivity |
|---|---|---|---|---|
| Amount X | | (%) | (μm) | (Ω cm) |
| Ca | 0.1 | 99.5 | 35 | 6 |
| | 0.3 | 99.2 | 36 | 6 × 10⁻² |
| | 0.5 | 99.1 | 39 | 8 × 10⁻⁴ |
| Sr | 0.1 | 99.3 | 38 | 3 |
| | 0.3 | 99.4 | 40 | 9 × 10⁻³ |
| | 0.5 | 98.8 | 41 | 6 × 10⁻⁴ |

### EXAMPLE 6

A sintered body was prepared under the same conditions as Example 1 other than that Ra was made to be Sm₂O₃ with a purity of 4N, and evaluated in the same manner. The relative density of the obtained sintered body was 95% or more, and the average grain size was 100 μm or less.

Further, as a result of evaluating the deposition, the amount of particles on the 8-inch wafer was 100 or less, and the generation of fractures or cracks after the sputtering evaluation could not be acknowledged. The results are shown in Table 6.

TABLE 6
(Sm₁₋ₓAₓMnO₃)

| Substitution | | Relative Density | Average Grain Size | Resistivity |
|---|---|---|---|---|
| Amount X | | (%) | (μm) | (Ω cm) |
| Ca | 0.1 | 98.2 | 21 | 8 |
| | 0.3 | 98 | 18 | 7 × 10⁻¹ |
| | 0.5 | 97.1 | 12 | 7 × 10⁻² |
| Sr | 0.1 | 97.9 | 14 | 4 |
| | 0.3 | 96.5 | 10 | 3 × 10⁻¹ |
| | 0.5 | 96.1 | 7 | 6 × 10⁻³ |

### EXAMPLE 7

A sintered body was prepared under the same conditions as Example 1 other than that Ra was made to be Eu₂O₃ with a purity of 4N, and evaluated in the same manner. The relative density of the obtained sintered body was 95% or more, and the average grain size was 100 μm or less.

Further, as a result of evaluating the deposition, the amount of particles on the 8-inch wafer was 100 or less, and the generation of fractures or cracks after the sputtering evaluation could not be acknowledged. The results are shown in Table 7.

TABLE 7
(Eu₁₋ₓAₓMnO₃)

| Substitution | | Relative Density | Average Grain Size | Resistivity |
|---|---|---|---|---|
| Amount X | | (%) | (μm) | (Ω cm) |
| Ca | 0.1 | 98.7 | 29 | 7 |
| | 0.3 | 98.7 | 26 | 5 × 10⁻¹ |
| | 0.5 | 96.9 | 18 | 2 × 10⁻² |
| Sr | 0.1 | 99 | 34 | 6 |
| | 0.3 | 98.3 | 28 | 9 × 10⁻² |
| | 0.5 | 97.7 | 22 | 7 × 10⁻⁴ |

### EXAMPLE 8

A sintered body was prepared under the same conditions as Example 1 other than that Ra was made to be Gd₂O₃ with a purity of 4N, and evaluated in the same manner. The relative density of the obtained sintered body was 95% or more, and the average grain size was 100 μm or less.

Further, as a result of evaluating the deposition, the amount of particles on the 8-inch wafer was 100 or less, and the generation of fractures or cracks after the sputtering evaluation could not be acknowledged. The results are shown in Table 8.

TABLE 8
(Gd₁₋ₓAₓMnO₃)

| Substitution | | Relative Density | Average Grain Size | Resistivity |
|---|---|---|---|---|
| Amount X | | (%) | (μm) | (Ω cm) |
| Ca | 0.1 | 99.8 | 53 | 7 |
| | 0.3 | 99.8 | 62 | 8 × 10⁻² |
| | 0.5 | 99.1 | 59 | 6 × 10⁻³ |
| Sr | 0.1 | 99.9 | 55 | 7 |
| | 0.3 | 99.6 | 58 | 5 × 10⁻² |
| | 0.5 | 98.9 | 67 | 9 × 10⁻⁴ |

### EXAMPLE 9

A sintered body was prepared under the same conditions as Example 1 other than that Ra was made to be Dy₂O₃ with a purity of 4N, and evaluated in the same manner. The relative density of the obtained sintered body was 95% or more, and the average grain size was 100 μm or less.

Further, as a result of evaluating the deposition, the amount of particles on the 8-inch wafer was 100 or less, and the generation of fractures or cracks after the sputtering evaluation could not be acknowledged. The results are shown in Table 9.

TABLE 9
(Dy₁₋ₓAₓMnO₃)

| Substitution | | Relative Density | Average Grain Size | Resistivity |
|---|---|---|---|---|
| Amount X | | (%) | (μm) | (Ω cm) |
| Ca | 0.1 | 99.6 | 44 | 8 |
| | 0.3 | 99.1 | 36 | 8 × 10⁻² |
| | 0.5 | 99 | 30 | 1 × 10⁻² |
| Sr | 0.1 | 99.7 | 39 | 5 |
| | 0.3 | 99.5 | 37 | 6 × 10⁻² |
| | 0.5 | 98.8 | 30 | 4 × 10⁻³ |

### EXAMPLE 10

The sintered body of Ra_{0.9}Ca_{0.1}MnO₃ (Ra: T, Ce, Pr, Sm, Dy) prepared in Examples 1 to 9 was processed into a target shape for evaluating the sputtering characteristics, and the amount of particles generated and post-sputtering cracks were examined by performing deposition via DC sputtering.

As a result, every target showed favorable results where 50 or less particles were generated on the film deposited on a 6-inch wafer, and the generation of fractures or cracks after the sputtering evaluation could not be acknowledged. The results are shown in Table 10.

TABLE 10

| Target Composition | Particles | Cracks |
|---|---|---|
| Y_{0.9}Ca_{0.1}MnO₃ | 31 | None |
| Ce_{0.9}Ca_{0.1}MnO₃ | 38 | None |
| Pr_{0.9}Ca_{0.1}MnO₃ | 22 | None |
| Sm_{0.9}Ca_{0.1}MnO₃ | 27 | None |
| Dy_{0.9}Ca_{0.1}MnO₃ | 34 | None |

### EXAMPLE 11

The sintered body of Ra_{0.9}Sr_{0.1}MnO₃ (Ra: La, Nd, Eu, Gd) prepared in Examples 1 to 9 was processed into a target shape for evaluating the sputtering characteristics, and the amount of particles generated and post-sputtering cracks were examined by performing deposition via DC sputtering.

As a result, every target showed favorable results where 50 or less particles were generated on the film deposited on a 6-inch wafer, and the generation of fractures or cracks after the sputtering evaluation could not be acknowledged. The results are shown in Table 11.

TABLE 11

| Target Composition | Particles | Cracks |
|---|---|---|
| La_{0.9}Sr_{0.1}MnO₃ | 18 | None |
| Nd_{0.9}Sr_{0.1}MnO₃ | 22 | None |
| Eu_{0.9}Sr_{0.1}MnO₃ | 37 | None |
| Gd_{0.9}Sr_{0.1}MnO₃ | 26 | None |

### COMPARATIVE EXAMPLE 2

A sintered body was prepared and evaluated under the same conditions as Comparative Example 1 other than that Ra was made to be La, Ce, Pr, Nd, Sm, Eu, Gd, Dy. When Ca or Sr Substitution x was 0.7, every sintered body generated numerous cracks after the heat treatment, and could not be processed into a target.

Further, where x=1.0, the resistivity was 100 Ωcm or more, and, after DC sputtering, numerous cracks and fractures were generated in the target. In addition, there were over 100 particles.

Accordingly, it is evident that the condition of 0<x≦0.5 of this invention is extremely important.

### INDUSTRIAL APPLICABILITY

The perovskite oxide ceramic material of this invention represented with the chemical formula of Ra₁₋ₓAₓBO_{3-α} (wherein Ra represents a rare earth element consisting of Y, Sc and lanthanoid; A represents Ca, Mg, Ba or Sr; and B represents a transition metal element such as Mn, Fe, Ni, Co or Cr) is useful as an oxide material having low electrical resistance, and can be used as an oxygen electrode of a solid-oxide fuel cell or an electrode material of a semiconductor memory.

Further, this system shows colossal magneto-resistance effect (CMR) at low temperatures, and applications to magnetic sensors utilizing this feature or to RRAM, which is attracting attention in recent years, are possible. The high density sputtering target of this invention is extremely important as the foregoing deposition materials.

1. A sputtering target that is a perovskite oxide represented by the chemical formula of Ra₁₋ₓAₓBO_{3-α} (wherein Ra represents a rare earth element consisting of Y, SC and lanthanoid; A represents Ca, Mg, Ba or Sr; B represents a transition metal element such as Mn, Fe, Ni, Co, or Cr; and 0<x≦0.5), and wherein the target has a relative density of 95% or more, an average crystal grain size of 100 μm or less a resistivity of 10 Ωcm or less, and a purity of 3N or more.

2-3. (canceled)
